(19) United States
(12) Patent Application Publication
(10) Pub. No.: US 2019/0096710 A1
(43) Pub. Date: Mar. 28, 2019

(54) SUBSTRATE PROCESSING APPARATUS, SUBSTRATE PROCESSING METHOD AND RECORDING MEDIUM

(71) Applicant: Tokyo Electron Limited, Tokyo (JP)

(72) Inventors: Hideaki Sato, Koshi City (JP); Hiroki Ohno, Tokyo (JP); Yoshinori Nishiwaki, Tokyo (JP); Takao Inada, Koshi City (JP); Hisashi Kawano, Koshi City (JP)

(21) Appl. No.: 16/143,918

(22) Filed: Sep. 27, 2018

(30) Foreign Application Priority Data
Sep. 28, 2017 (JP) 2017-188573

(51) Int. Cl. H01L 21/67; H01L 21/311

(52) U.S. Cl. CPC H01L 21/67086; H01L 21/31111; H01L 21/67253

(57) ABSTRACT

A substrate processing apparatus, a substrate processing method and a recording medium capable of suppressing precipitation of a silicon oxide while improving selectivity for etching a silicon nitride film are provided. The substrate processing apparatus includes a SiO₂ precipitation inhibitor supply unit and a control unit. The SiO₂ precipitation inhibitor supply unit is configured to supply a SiO₂ precipitation inhibitor to be mixed into a phosphoric acid processing liquid used in performing an etching processing in a substrate processing tub. The control unit is configured to set a SiO₂ precipitation inhibitor concentration contained in the phosphoric acid processing liquid based on a temperature of the phosphoric acid processing liquid, and configured to control a supply amount of the SiO₂ precipitation inhibitor to achieve the set SiO₂ precipitation inhibitor concentration.

### CROSS-REFERENCE TO RELATED APPLICATION

This application claims the benefit of Japanese Patent Application No. 2017-188573 filed on Sep. 28, 2017, the entire disclosures of which are incorporated herein by reference.

### TECHNICAL FIELD

The various aspects and embodiments described herein pertain generally to a substrate processing apparatus, a substrate processing method and a recording medium.

### BACKGROUND

Conventionally, in a substrate processing apparatus, there is known an etching processing of selectively etching, between a silicon nitride film (SiN) and a silicon oxide film (SiO₂) formed on a substrate, the silicon nitride film by immersing the substrate in a phosphoric acid processing liquid (see Patent Document 1).

In this etching processing, it is known that selectivity for etching the silicon nitride film is improved if a silicon concentration of the phosphoric acid processing liquid is increased. Meanwhile, it is also known that if the silicon concentration of the phosphoric acid processing liquid is too high, a silicon oxide (SiO₂) is precipitated on the silicon oxide film.

For this reason, in the substrate processing apparatus, the silicon concentration of the phosphoric acid processing liquid is adjusted to fall within a constant range.
Patent Document 1: Japanese Patent Laid-open Publication No. 2013-232593

### SUMMARY

In the aforementioned substrate processing apparatus, however, there is still a room for improvement in that the precipitation of the silicon oxide needs to be suppressed while improving the selectivity for etching the silicon nitride film.

In view of the foregoing, exemplary embodiments provide a substrate processing apparatus, a substrate processing method and a recording medium capable of suppressing the precipitation of the silicon oxide while improving the selectivity for etching the silicon nitride film.

In one exemplary embodiment, a substrate processing apparatus includes a SiO₂ precipitation inhibitor supply unit and a control unit. The SiO₂ precipitation inhibitor supply unit is configured to supply a SiO₂ precipitation inhibitor to be mixed into a phosphoric acid processing liquid used in performing an etching processing in a substrate processing tub. The control unit is configured to set a SiO₂ precipitation inhibitor concentration contained in the phosphoric acid processing liquid based on a temperature of the phosphoric acid processing liquid, and configured to control a supply amount of the SiO₂ precipitation inhibitor to achieve the set SiO₂ precipitation inhibitor concentration.

According to the exemplary embodiments, it is possible to suppress the precipitation of the silicon oxide while improving the selectivity for etching the silicon nitride film.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic plan view of a substrate processing apparatus;

FIG. 2 is a schematic block diagram illustrating a configuration of a supply system of a processing tub for etching;

FIG. 3 is a schematic block diagram illustrating a configuration of an exhaust system of the processing tub for etching;

FIG. 4 is a flowchart for describing an etching processing;

FIG. 5 is a flowchart for describing a method of supplying a SiO₂ precipitation inhibitor in a second etching processing;

FIG. 6 is a table showing a relationship between a temperature of a first etching liquid and a concentration of the SiO₂ precipitation inhibitor; and

FIG. 7 is a flowchart for describing an exhausting processing of the processing tub for etching.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, a substrate processing apparatus, a substrate processing method and a recording medium according to exemplary embodiments will be described in detail with reference to accompanying drawings. Here, however, it should be noted that the exemplary embodiments are not limiting.

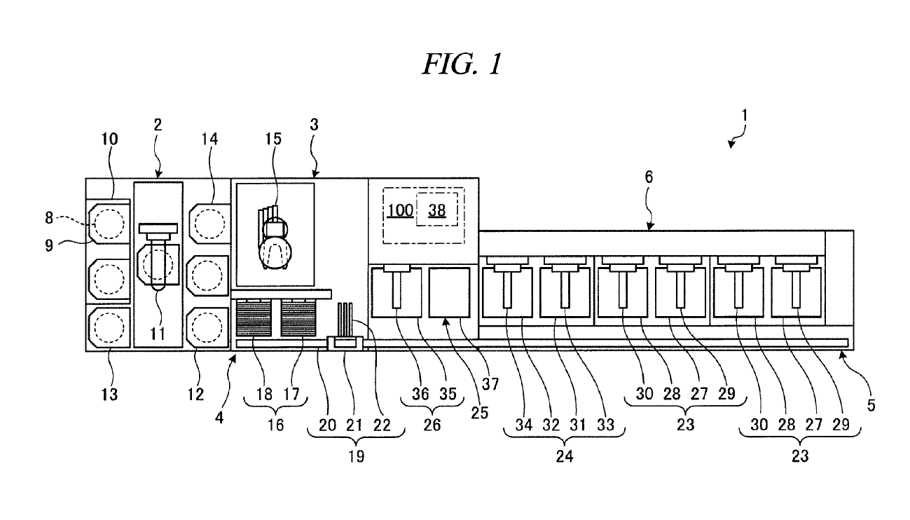

As depicted in FIG. 1, a substrate processing apparatus 1 according to a first exemplary embodiment includes a carrier carry-in/out unit 2, a lot forming unit 3, a lot placing unit 4, a lot transferring unit 5, a lot processing unit 6 and a control unit 100. FIG. 1 is a schematic plan view of the substrate processing apparatus 1. Here, a direction orthogonal to a horizontal direction will be defined as a vertical direction.

The carrier carry-in/out unit 2 is configured to perform a carry-in and a carry-out of a carrier 9 in which a plurality (e.g., 25 sheets) of substrates (silicon wafers) 8 are vertically arranged in a horizontal posture.

The carrier carry-in/out unit 2 is equipped with a carrier stage 10 configured to place multiple carriers 9 thereon; a carrier transfer device 11 configured to transfer the carrier 9; carrier stocks 12 and 13 configured to place therein the carrier 9 temporarily; and a carrier placing table 14 configured to place the carrier 9 thereon.

The carrier carry-in/out unit 2 transfers the carrier 9, which is carried onto the carrier stage 10 from the outside, to the carrier stock 12 or the carrier placing table 14 by using the carrier transfer device 11. That is, the carrier carry-in/out unit 2 transfers the carrier 9 accommodating therein the plurality of substrates 8 before being processed by the lot processing unit 6 to the carrier stock 12 or the carrier placing table 14.

The carrier stock 12 temporarily places therein the carrier 9 which accommodates therein the plurality of substrates 8 before being processed by the lot processing unit 6.

The plurality of substrates 8 are carried out from the carrier 9, which is carried onto the carrier placing table 14 while accommodating therein the plurality of substrates 8 before being processed by the lot processing unit 6, by a substrate transfer device 15 to be described later.

Further, the plurality of substrates 8 after being processed by the lot processing unit 6 is carried from the substrate transfer device 15 into the carrier 9 which is placed on the carrier placing table 14 and does not accommodate the substrates 8 therein.

The carrier carry-in/out unit 2 carries the carrier 9, which is placed on the carrier placing table 14 and accommodates therein the plurality of substrates 8 after being processed by the lot processing unit 6, to the carrier stock 13 or the carrier stage 10 by using the carrier transfer device 11.

The carrier stock 13 temporarily accommodates therein the plurality of substrates 8 after being processed by the lot processing unit 6. The carrier 9 transferred to the carrier stage 10 is carried to the outside.

The lot forming unit 3 is equipped with the substrate transfer device 15 configured to transfer a plurality (e.g., 25 sheets) of substrates 8. The lot forming unit 3 performs a transfer of the plurality (e.g., 25 sheets) of substrates 8 by the substrate transfer device 15 twice and forms a lot composed of a multiplicity (e.g., 50 sheets) of substrates 8.

The lot forming unit 3 forms the lot by transferring the multiplicity of substrates 8 from the carriers 9 placed on the carrier placing table 14 to the lot placing unit 4 by using the carrier transfer device 15 and placing the multiplicity of substrates 8 on the lot placing unit 4.

The multiplicity of substrates 8 belonging to the single lot are processed by the lot processing unit 6 at the same time. When forming the lot, the substrates 8 may be arranged such that surfaces thereof having patterns formed thereon face each other or such that the surfaces thereof having the patterns formed thereon all face to one direction.

Further, in the lot forming unit 3, the multiplicity of substrates 8 are transferred by the substrate transfer device 15 to the carrier 9 from the lot placed in the lot placing unit 4 after being subjected to the processing in the lot processing unit 6.

The substrate transfer device 15 is equipped with, as a substrate supporting unit configured to support the multiplicity of substrates 8, two types of substrate supporting unit: a before-processed substrate supporting unit (not shown) configured to support the substrates 8 before being subjected to a processing; and an after-processed substrate supporting unit (not shown) configured to support the processed substrates 8. Accordingly, particles or the like adhering to the substrates 8 before being processed may be suppressed from adhering to the substrates 8 after being processed.

The substrate transfer device 15 changes a posture of the substrates 8 from a horizontal posture to a vertical posture and from the vertical posture to the horizontal posture while transferring the substrates 8.

In the lot placing unit 4, the lot which is transferred between the lot forming unit 3 and the lot processing unit 6 by the lot transferring unit 5 is temporarily placed (stands by) on the lot placing table 16.

The lot placing unit 4 is equipped with a carry-in side lot placing table 17 and a carry-out side lot placing table 18.

The carry-in side lot placing table 17 is configured to place thereon the lot before being processed. The carry-out side lot placing table 18 is configured to place thereon the lot after being processed.

On each of the carry-in side lot placing table 17 and the carry-out side lot placing table 18, the multiplicity of substrates 8 corresponding to the single lot are arranged in a forward-backward direction with the vertical posture.

The lot transferring unit 5 is configured to transfer the lot between the lot placing unit 4 and the lot processing unit 6 and within the lot processing unit 6.

The lot transferring unit 5 is equipped with the lot transfer device 19 configured to transfer the lot. The lot transfer device 19 includes a rail 20 extended along the lot placing unit 4 and the lot processing unit 6; and a moving body 21 configured to be moved along the rail 20 while holding the lot.

The moving body 21 is provided with a substrate holding body 22 configured to hold the multiplicity of substrates 8 arranged in the forward-backward direction with the vertical posture.

The lot transferring unit 5 receives the lot placed on the carry-in side lot placing table 17 with the substrate holding body 22 of the lot transfer device 19 and delivers the received lot to the lot processing unit 6.

Further, the lot transferring unit 5 receives the lot processed by the lot processing unit 6 with the substrate holding body 22 of the lot transfer device 19 and delivers the received lot to the carry-out side lot placing table 18.

Further, the lot transferring unit 5 also performs the transfer of the lot within the lot processing unit 6 by using the lot transfer device 19.

The lot processing unit 6 is configured to perform a processing such as etching, cleaning and drying on the single lot composed of the multiplicity of substrates 8 arranged in the forward-backward direction with the vertical posture.

The lot processing unit 6 includes two etching apparatuses 23 configured to perform an etching processing on the lot; a cleaning apparatus 24 configured to perform a cleaning processing on the lot; a substrate holding body cleaning apparatus 25 configured to perform a cleaning processing on the substrate holding body 22; and a drying apparatus 26 configured to perform a drying processing on the lot. Further, the number of the etching apparatuses 23 is not limited to 2 and may be one or more than 2.

Each etching apparatus 23 includes a processing tub 27 for etching, a processing tub 28 for rinsing, and substrate elevating devices 29 and 30.

The processing tub 27 for etching stores therein a processing liquid for etching (hereinafter, referred to as “etching liquid”). The processing tub 28 for rinsing stores therein a processing liquid for rinsing (pure water or the like). Details of the processing tub 27 for etching will be described later.

The multiple number of substrates 8 constituting the single lot are held by the substrate elevating device 29 (30) while being arranged in the forward-backward direction with the vertical posture.

The etching apparatus 23 receives the lot from the substrate holding body 22 of the lot transfer device 19 with the substrate elevating device 29, and the received lot is moved up and down by the substrate elevating device 29. Accordingly, the lot is immersed in the etching liquid in the processing tub 27, so that an etching processing is performed.

Thereafter, the etching apparatus 23 takes out the lot from the processing tub 27 by raising the substrate elevating device 29, and delivers the lot to the substrate holding body 22 of the lot transfer device 19 from the substrate elevating device 29.

Then, the lot is received by the substrate elevating device 30 from the substrate holding body 22 of the lot transfer device 19, and the received lot is moved up and down by the substrate elevating device 30. Accordingly, the lot is immersed in the processing liquid for rinsing in the processing tub 28, so that a rinsing processing is performed.

Thereafter, the etching apparatus 23 takes out the lot from the processing tub 28 by raising the substrate elevating device 30, and delivers the lot to the substrate holding body 22 of the lot transfer device 19 from the substrate elevating device 30.

The cleaning apparatus 24 is equipped with a processing tub 31 for cleaning, a processing tub 32 for rinsing, and substrate elevating devices 33 and 34.

The processing tub 31 for cleaning stores therein a processing liquid for cleaning (SC-1 or the like). The processing tub 32 for rinsing stores therein a processing liquid for rinsing (pure water or the like). The multiplicity of substrates 8 belonging to the single lot are held by each of the substrate elevating devices 33 and 34 while being arranged in the forward-backward direction with the vertical posture.

The drying apparatus 26 is equipped with a processing tub 35 and a substrate elevating device 36 configured to be moved up and down with respect to the processing tub 35.

A processing gas for drying (isopropyl alcohol) is supplied into the processing tub 35. The multiplicity of substrates 8 corresponding to the single lot are held by the substrate elevating device 36 while being arranged in the forward-backward direction with the vertical posture.

The drying apparatus 26 receives the lot from the substrate holding body 22 of the lot transfer device 19 with the substrate elevating device 36, and carries the received lot into the processing tub 35 by moving the receive lot up and down with the substrate elevating device 36. Then, a drying processing is performed on the lot by the processing gas for drying supplied into the processing tub 35. Thereafter, the drying apparatus 26 raises the lot with the substrate elevating device 36 and delivers the lot after being subject to the drying processing to the substrate holding body 22 of the lot transfer device 19 from the subtract elevating device 36.

The substrate holding body cleaning apparatus 25 includes a processing tub 37 and is configured to supply a processing liquid for cleaning and a drying gas into this processing tub 37. By supplying the drying gas after supplying the processing liquid for cleaning to the substrate holding body 22 of the lot transfer device 19, the substrate holding body cleaning apparatus 25 performs a cleaning processing on the substrate holding body 22.

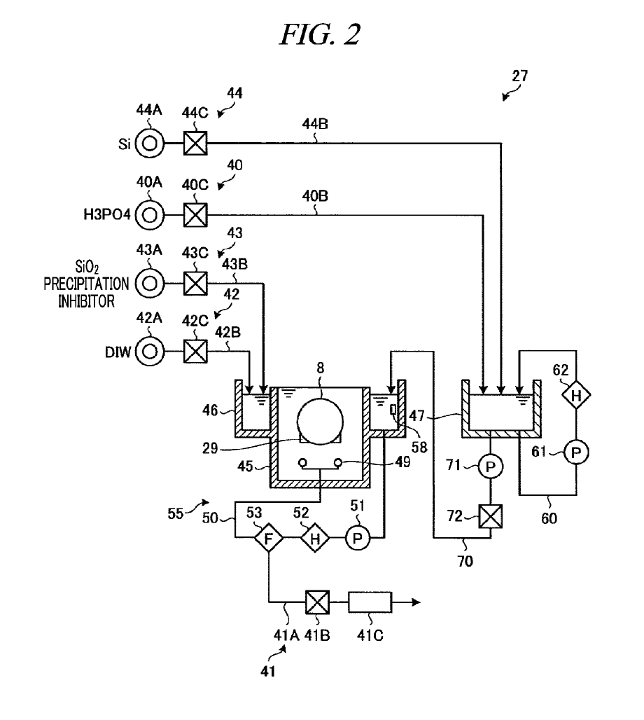

Now, a supply system for the processing tub 27 for etching will be explained with reference to FIG. 2. FIG. 2 is a schematic block diagram illustrating a configuration of the supply system of the processing tub 27 for etching.

In the processing tub 27 for etching, between a nitride film (SiN) and an oxide film (SiO₂) formed on the substrate 8, only the nitride film is selectively etched by using an etching liquid.

In the etching processing for the nitride film, a solution, prepared by adding a silicon (Si)-containing compound to a phosphoric acid (H₃PO₄) aqueous solution, with an adjusted silicon concentration is generally used as the etching liquid. As a way to adjust the silicon concentration, a method of dissolving silicon by immersing a dummy substrate in a phosphoric acid aqueous solution (seasoning), a method of dissolving a silicon-containing compound such as colloidal silica in the phosphoric acid aqueous solution, or the like may be used. Further, there is also employed a method of adjusting the silicon concentration by adding a silicon-containing compound aqueous solution to the phosphoric acid aqueous solution.

In the etching processing, by increasing the silicon concentration of the etching liquid, selectivity for etching only the nitride film can be improved. If, however, the silicon concentration of the etching liquid is increased excessively as the nitride film is dissolved in the etching liquid through the etching processing, the silicon dissolved in the etching liquid may be precipitated on the oxide film as a silicon oxide.

In the present exemplary embodiment, as an etching liquid, a first etching liquid in which the silicon-containing compound aqueous solution is mixed with the phosphoric acid aqueous solution as the phosphoric acid processing liquid and a second etching liquid in which a SiO₂ precipitation inhibitor is mixed with the first etching liquid are used. Further, in the following description, when it is not required to distinguish the first etching liquid and the second etching liquid, they will be just referred to as the etching liquid.

The SiO₂ precipitation inhibitor is not particularly limited as long as it contains a component capable of suppressing precipitation of a silicon oxide by stabilizing silicon ions dissolved in the phosphoric acid aqueous solution in a dissolved state. By way of example, a hexafluorosilicic acid (H₂SiF₆) aqueous solution containing a fluorine component may be used. Here, an additive such as ammonia may be added to stabilize hexafluorosilicic acid in the aqueous solution.

The SiO₂ precipitation inhibitor may be implemented by, by way of non-limiting example, ammonium hexafluorosilicate ((NH₄)₂SiF₆), sodium hexafluorosilicate (Na₂SiF₆), or the like.

The processing tub 27 for etching is equipped with a phosphoric acid aqueous solution supply unit 40, a phosphoric acid aqueous solution drain unit 41, a pure water supply unit 42, a SiO₂ precipitation inhibitor supply unit 43, a silicon supply unit 44, an inner tub 45, an outer tub 46 and a temperature control tank 47.

The phosphoric acid aqueous solution supply unit 40 includes a phosphoric acid aqueous solution source 40A, a phosphoric acid aqueous solution supply line 40B and a first flow rate controller 40C.

The phosphoric acid aqueous solution source 40A is a tank configured to store the phosphoric acid aqueous solution therein. The phosphoric acid aqueous solution supply line 40B is configured to connect the phosphoric acid aqueous solution source 40A and the temperature control tank 47 and configured to supply the phosphoric acid aqueous solution from the phosphoric acid aqueous solution source 40A to the temperature control tank 47.

The first flow rate controller 40C is provided at the phosphoric acid aqueous solution supply line 40B and configured to adjust a flow rate of the phosphoric acid aqueous solution supplied to the temperature control tank 47. The first flow rate controller 40C may be composed of an opening/closing valve, a flow rate control valve, a flowmeter, and so forth.

The pure water supply unit 42 includes a pure water source 42A, a pure water supply line 42B, and a second flow rate controller 42C. The pure water supply unit 42 is configured to supply pure water (DIW) into the outer tub 46 to replenish moisture that has evaporated as the etching liquid is heated.

The pure water supply line 42B is configured to connect the pure water source 42A and the outer tub 46 and configured to supply the pure water of a preset temperature from the pure water source 42A into the outer tub 46.

The second flow rate controller 42C is provided at the pure water supply line 42B and configured to adjust a flow rate of the pure water supplied to the outer tub 46. The second flow rate controller 42C is composed of an opening/closing valve, a flow rate control valve, a flowmeter, and so forth.

The SiO₂ precipitation inhibitor supply unit 43 includes a SiO₂ precipitation inhibitor source 43A, a SiO₂ precipitation inhibitor supply line 43B, and a third flow rate controller 43C. The SiO₂ precipitation inhibitor supply unit 43 is configured to supply the SiO₂ precipitation inhibitor into the outer tub 46 to generate the second etching liquid. Further, the SiO₂ precipitation inhibitor supply unit 43 is configured to supply the SiO₂ precipitation inhibitor into the outer tub 46 to replenish the SiO₂ precipitation inhibitor that has evaporated as the second etching liquid is heated.

The SiO₂ precipitation inhibitor source 43A is a tank which stores the SiO₂ precipitation inhibitor therein. The SiO₂ precipitation inhibitor supply line 43B is configured to connect the SiO₂ precipitation inhibitor source 43A and the outer tub 46 and configured to supply the SiO₂ precipitation inhibitor from the SiO₂ precipitation inhibitor source 43A into the outer tub 46.

The third flow rate controller 43C is provided at the SiO₂ precipitation inhibitor supply line 43B and configured to adjust a flow rate of the SiO₂ precipitation inhibitor supplied to the outer tub 46. The third flow rate controller 43C is composed of an opening/closing valve, a flow rate control valve, a flowmeter, and so forth.

The silicon supply unit 44 includes a silicon source 44A, a silicon supply line 44B and a fourth flow rate controller 44C.

The silicon source 44A is a tank which stores the silicon-containing compound aqueous solution therein. The silicon supply line 44B is configured to connect the silicon source 44A and the temperature control tank 47 and configured to supply the silicon-containing compound aqueous solution from the silicon source 44A into the temperature control tank 47.

The fourth flow rate controller 44C is provided at the silicon supply line 44B and configured to adjust a flow rate of the silicon-containing compound aqueous solution supplied to the temperature control tank 47. The fourth flow rate controller 44C is composed of an opening/closing valve, a flow rate control valve, a flowmeter, and so forth.

Further, the silicon-containing compound aqueous solution is supplied when generating a reserve liquid which is supplied when replacing the second etching liquid completely.

The inner tub 45 has an open top, and the etching liquid is supplied to near the top thereof. In the inner tub 45, the lot (the multiplicity of substrates 8) is immersed in the etching liquid by the substrate elevating device 29, so that the etching processing is performed on the substrates 8. The inner tub 45 constitutes a substrate processing tub.

The outer tub 46 is provided around an upper portion of the inner tub 45 and has an open top. The etching liquid overflown from the inner tub 45 is introduced into the outer tub 46. Further, the reserve liquid, which is the phosphoric acid aqueous solution mixed with the silicon-containing compound aqueous solution, is supplied into the outer tub 46 from the temperature control tank 47. Further, the pure water is supplied into the outer tub 46 from the pure water supply unit 42. Furthermore, the SiO₂ precipitation inhibitor is also supplied into the outer tub 46 from the SiO₂ precipitation inhibitor supply unit 43. The SiO₂ precipitation inhibitor supplied into the outer tub 46 is mixed into the etching liquid within the outer tub 46 or mixed into the reserve liquid supplied from the temperature control tank 47. That is, the SiO₂ precipitation inhibitor is mixed into the phosphoric acid aqueous solution in the outer tub 46.

The outer tub 46 and the inner tub 45 are connected by a first circulation line 50. One end of the first circulation line 50 is connected to the outer tub 46, and the other end of the first circulation line 50 is connected to a processing liquid supply nozzle 49 provided within the inner tub 45.

The first circulation line 50 is provided with a first pump 51, a first heater 52 and a filter 53 in sequence from the outer tub 46 side. The etching liquid within the outer tub 46 is introduced into the inner tub 45 from the processing liquid supply nozzle 49 after a temperature thereof is increased by the first heater 52. The first heater 52 heats the etching liquid to be supplied into the inner tub 45 to a first preset temperature suitable for the etching processing.

By driving the first pump 51, the etching liquid is fed into the inner tub 45 from the outer tub 46 through the first circulation line 50. Further, the etching liquid is flown back into the outer tub 46 by being overflown from the inner tub 45. In this way, a circulation path 55 of the etching liquid is formed. That is, the circulation path 55 is formed by the outer tub 46, the first circulation line 50 and the inner tub 45. In the circulation path 55, the inner tub 45, the outer tub 46 and the first heater 52 are provided in sequence from an upstream side of the circulation path 55. Further, the circulation path 55 is provided with a thermometer 58 configured to detect a temperature of the etching liquid. To elaborate, the thermometer 58 is provided at the outer tub 46.

In the temperature control tank 47, the phosphoric acid aqueous solution supplied from the phosphoric acid aqueous solution supply unit 40 and the silicon-containing compound aqueous solution supplied from the silicon supply unit 44 are mixed to produce the reserve liquid, and this reserve liquid is stored in the temperature control tank 47. Connected to the temperature control tank 47 is a second circulation line 60 through which the reserve liquid within the temperature control tank 47 is circulated. Further, one end of a supply line 70 is connected to the temperature control tank 47, and the other end of the supply line 70 is connected to the outer tub 46. The temperature control tank 47 serves as a reserve tank which stores the reserve liquid therein.

The second circulation line 60 is provided with a second pump 61 and a second heater 62. By driving the second pump 61 in a state that the second heater 62 is turned ON, the reserve liquid within the temperature control tank 47 is circulated with a temperature thereof increased. The second heater 62 heats the reserve liquid to a second preset temperature suitable for the etching processing. The second preset temperature may be equal to or different from the first preset temperature.

The supply line 70 is provided with a third pump 71 and a fifth flow rate controller 72. The fifth flow rate controller 72 is configured to adjust a flow rate of the reserve liquid supplied into the outer tub 46. The fifth flow rate controller 72 is composed of an opening/closing valve, a flow rate control valve, a flowmeter, and so forth.

The reserve liquid stored in the temperature control tank 47 is supplied into the outer tub 46 through the supply line 70 when replacing the whole or a part of the second etching liquid.

The phosphoric acid aqueous solution drain unit 41 is configured to drain the second etching liquid when replacing the whole or the part of the second etching liquid used in the etching processing. The phosphoric acid aqueous solution drain unit 41 includes a drain line 41A, a sixth flow rate controller 41B and a cooling tank 41C.

The drain line 41A is connected to the first circulation line 50. The sixth flow rate controller 41B is provided at the drain line 41A and configured to adjust a drain amount of the second etching liquid. The sixth flow rate controller 41B is composed of an opening/closing valve, a flow rate control valve, a flowmeter, and so forth. The cooling tank 41C temporarily stores therein and cools the second etching liquid flown through the drain line 41A.

Further, opening/closing operations of the opening/closing valves and opening degrees of the flow rate control valves, which constitute the first to sixth flow rate controllers 40C to 41B, are changed as actuators (not shown) are operated based on signals from the control unit 100. That is, the opening/closing valves and the flow rate control valves constituting the first to sixth flow rate controllers 40C to 41B are controlled by the control unit 100.

The phosphoric acid aqueous solution drain unit 41 is configured to drain the second etching liquid used in the etching processing. The phosphoric acid aqueous solution drain unit 41 includes a drain line 41A, a sixth flow rate controller 41B and a cooling tank 41C.

The drain line 41A is connected to the first circulation line 50. The sixth flow rate controller 41B is provided at the drain line 41A and configured to adjust a drain amount of the second etching liquid. The sixth flow rate controller 41B is composed of an opening/closing valve, a flow rate control valve, a flowmeter, and so forth. The cooling tank 41C temporarily stores and cools therein the second etching liquid flown through the drain line 41A.

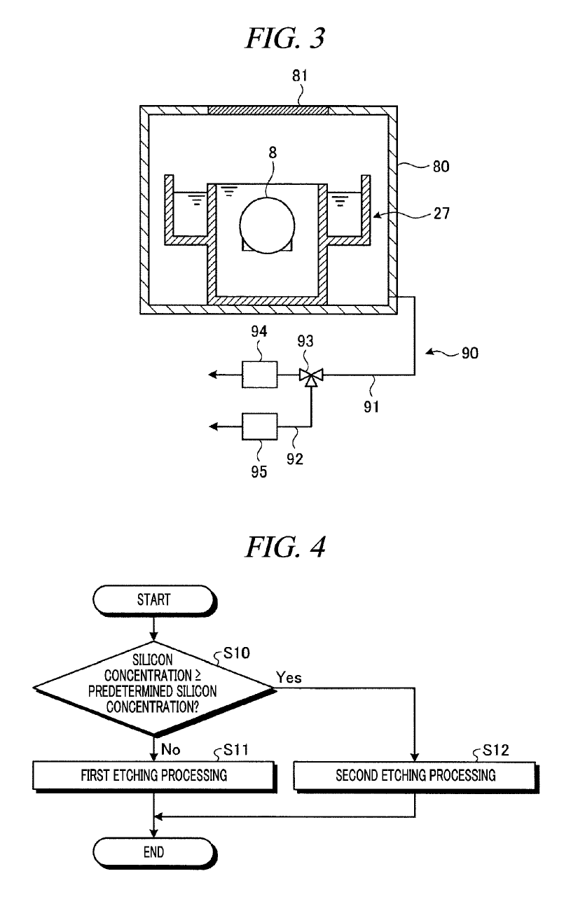

Now, an exhaust system of the processing tub 27 for etching will be explained with reference to FIG. 3. FIG. 3 is a schematic block diagram illustrating a configuration of the exhaust system of the processing tub 27 for etching.

The processing tub 27 for etching is accommodated in a processing chamber 80 into/from which the substrates 8 can be carried. In the processing chamber 80, a downflow is produced by a FFU (Fan Filter Unit) 81, and an atmosphere within the processing tub 27 is exhausted as an exhaust gas through an exhaust unit 90.

The exhaust unit 90 includes a first exhaust line 91, a second exhaust line 92, a switching valve 93, an acid-based processing unit 94, and an organic-based processing unit 95.

The first exhaust line 91 is configured to connect the processing chamber 80 to the outside. The first exhaust line 91 is provided with the switching valve 93 and the acid-based processing unit 94 in sequence from the processing chamber 80 side.

The second exhaust line 92 is connected to the first exhaust line 91 via the switching valve 93 and configured to connect the first exhaust line 91 to the outside. That is, the second exhaust line 92 is a line branched from the first exhaust line 91. The second exhaust line 92 is provided with the organic-based processing unit 95.

The acid-based processing unit 94 is provided at the first exhaust line 91 at a downstream side of the switching valve 93. The acid-based processing unit 94 is an exhaust gas processing device configured to purify an acidic component in the exhaust gas. The organic-based processing unit 95 is an exhaust gas processing device configured to purify an organic component in the exhaust gas. The acid-based processing unit 94 and the organic-based processing unit 95 are arranged in parallel.

The switching valve 93 switches a discharge direction of the exhaust gas to either the acid-based processing unit 94 or the organic-based processing unit 95 selectively when exhausting the exhaust gas from the processing chamber 80.

The switching of the discharge direction of the exhaust gas by the switching valve 93 is performed as an actuator (not shown) is operated based on a signal from the control unit 100. That is, the switching valve 93 is controlled by the control unit 100.

Referring back to FIG. 1, the control unit 100 controls operations of individual components (the carrier carry-in/out unit 2, the lot forming unit 3, the lot placing unit 4, the lot transferring unit 5, and the lot processing unit 6) of the substrate processing apparatus 1. The control unit 100 controls the operations of the individual components of the substrate processing apparatus 1 based on signals from switches or the like.

The control unit 100 may be implemented by, for example, a computer and has a computer-readable recording medium 38. The recording medium 38 stores therein programs for controlling various types of processings performed in the substrate processing apparatus 1.

The control unit 100 controls the operation of the substrate processing apparatus 1 by reading and executing the programs stored in the recording medium 38. Further, the programs are stored in the compute-readable recording medium 38 and may be installed to the recording medium 38 of the control unit 100 from another recording medium.

The computer-readable recording medium 38 may be implemented by, by way of non-limiting example, a hard disk HD, a flexible disk FD, a compact disk CD, a magnet optical disk MO, a memory card, or the like.

Now, the etching processing in the processing tub 27 for etching will be discussed with reference to FIG. 4. FIG. 4 is a flowchart for describing the etching processing.

When beginning the etching processing, the first etching liquid has been supplied in the inner tub 45 and the outer tub 46, and a first etching processing using the first etching liquid is first performed. That is, the etching processing is performed in a state that the SiO₂ precipitation inhibitor is not mixed.

After the etching processing is begun, the control unit 100 determines whether the silicon concentration of the first etching liquid has become equal to or higher than a predetermined silicon concentration (S10). The predetermined silicon concentration is previously set, and is a concentration at which the silicon oxide is precipitated.

The control unit 100 makes a determination that the silicon concentration has become equal to or higher than the predetermined silicon concentration when an elapsed time as a processing time after the beginning of the etching processing with the first etching liquid has reached a preset first elapsed time. The preset first elapsed time is set by, for example, an experiment, and is a period during which the silicon concentration of the first etching liquid reaches the predetermined silicon concentration or higher.

If the silicon concentration is smaller than the predetermined silicon concentration (S10: No), the control unit 100 performs the first etching processing (S11).

In the first etching processing, the control unit 100 adjusts a phosphoric acid concentration of the first etching liquid to a predetermined phosphoric acid concentration. If the first etching liquid is heated, moisture of the first etching liquid evaporates, so that the phosphoric acid concentration of the first etching liquid is increased.

For this reason, the control unit 100 supplies DIW to the first etching liquid and adjusts the phosphoric acid concentration of the first etching liquid to the predetermined phosphoric acid concentration. That is, the control unit 100 replenishes the moisture evaporated from the first etching liquid.

If the silicon concentration is equal to or higher than the predetermined silicon concentration (S10: Yes), the control unit 100 performs a second etching processing (S12). The second etching processing is a processing of performing the etching with the second etching liquid containing the SiO₂ precipitation inhibitor mixed therein.

In the second etching processing, the control unit 100 generates the second etching liquid by supplying the SiO₂ precipitation inhibitor to the outer tub 46 from the SiO₂ precipitation inhibitor supply unit 43. The control unit 100 controls a supply amount of the SiO₂ precipitation inhibitor such that a SiO₂ precipitation inhibitor concentration as a ratio of the SiO₂ precipitation inhibitor contained in the second etching liquid reaches a set SiO₂ precipitation inhibitor concentration.

Further, the control unit 100 adjusts the phosphoric acid concentration of the second etching liquid to a predetermined phosphoric acid concentration. The same as in the first etching processing, the control unit 100 supplies the DIW to the outer tub 46 from the pure water supply unit 42 in the second etching processing to replenish the moisture evaporated from the second etching liquid.

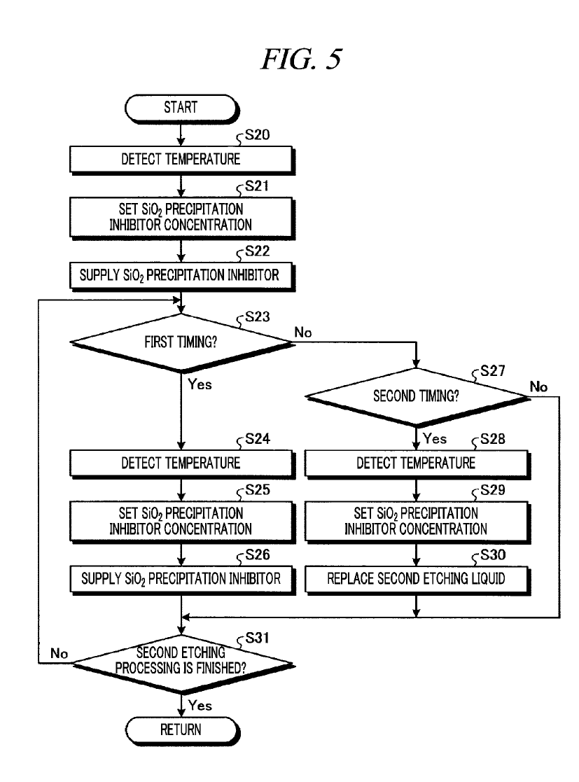

Here, a method of supplying the SiO₂ precipitation inhibitor in the second etching processing will be explained with reference to FIG. 5. FIG. 5 is a flowchart for describing the method of supplying the SiO₂ precipitation inhibitor in the second etching processing.

When beginning the second etching processing, the control unit 100 detects a temperature of the first etching liquid by the thermometer 58 provided at the outer tub 46 (S20). The control unit 100 sets a concentration of the SiO₂ precipitation inhibitor based on the detected temperature (S21).

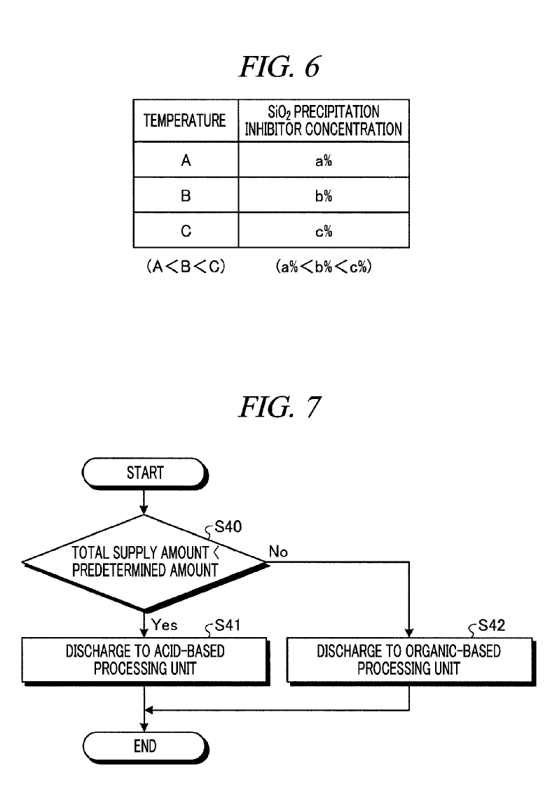

The control unit 100 sets the concentration of the SiO₂ precipitation inhibitor based on the temperature of the first etching liquid by using a table shown in FIG. 6, for example. FIG. 6 is a table showing a relationship between the temperature of the first etching liquid and the concentration of the SiO₂ precipitation inhibitor.

By way of example, if the temperature of the first etching liquid is “A,” the concentration of the SiO₂ precipitation inhibitor is set to “a %.” If the temperature of the first etching liquid is “B (>A),” the concentration of the SiO₂ precipitation inhibitor is set to “b % (>a %).” Further, if the temperature of the first etching liquid is “C (>B),” the concentration of the SiO₂ precipitation inhibitor is set to “c % (>b %).” That is, the control unit 100 sets the concentration of the SiO₂ precipitation inhibitor to a higher value as the temperature of the first etching liquid increases.

The control unit 100 controls the SiO₂ precipitation inhibitor supply unit 43 to supply the SiO₂ precipitation inhibitor to achieve the set SiO₂ precipitation inhibitor concentration (S22). The control unit 100 controls the supply amount of the SiO₂ precipitation inhibitor based on the concentration of the SiO₂ precipitation inhibitor.

The control unit 100 determines whether it is a first timing (S23). The first timing is a timing when the concentration of the SiO₂ precipitation inhibitor of the second etching liquid is adjusted, and is previously set. To elaborate, the control unit 100 determines that it is the first timing if an elapsed time after the beginning of the second etching processing reaches a preset adjusting time.

If the second etching liquid is heated, the SiO₂ precipitation inhibitor of the second etching liquid is evaporated, so that the SiO₂ precipitation inhibitor concentration of the second etching liquid is decreased. For this reason, the control unit 100 controls the SiO₂ precipitation inhibitor supply unit 43 to supply the SiO₂ precipitation inhibitor at the first timing to adjust the SiO₂ precipitation inhibitor concentration.

Further, the preset adjusting time has multiple adjusting times, and the control unit 100 determines that it is the first timing whenever the multiple adjusting times are elapsed.

When it is the first timing (S23: Yes), the control unit 100 detects a temperature of the second etching liquid by the thermometer 58 (S24), and sets the SiO₂ precipitation inhibitor concentration based on the detected temperature (S25). By way of example, the control unit 100 sets the SiO₂ precipitation inhibitor concentration based on the temperature of the second etching liquid by using the table shown in FIG. 6. Further, the control unit 100 may set the SiO₂ precipitation inhibitor concentration by using a table different from the table shown in FIG. 6.

The control unit 100 controls the SiO₂ precipitation inhibitor supply unit 43 to supply the SiO₂ precipitation inhibitor to the outer tub 46 to achieve the set SiO₂ precipitation inhibitor concentration (S26). A supply amount of the SiO₂ precipitation inhibitor is previously set based on an elapsed time, and the control unit 100 controls the SiO₂ precipitation inhibitor concentration by controlling the supply amount of the SiO₂ precipitation inhibitor based on the elapsed time.

When it is not the first timing (S23: No), the control unit 100 determines whether it is a second timing (S27). The second timing is a timing when a part of the second etching liquid is drained, and is previously set. To elaborate, the control unit 100 determines that it is the second timing if an elapsed time after the beginning of the second etching processing reaches a preset draining time.

If it is the second timing (S27: Yes), the control unit 100 detects the temperature of the second etching liquid by the thermometer 58 (S28), and sets the SiO₂ precipitation inhibitor concentration based on the detected temperature (S29). The same as in the aforementioned process S25, for example, the control unit 100 sets the SiO₂ precipitation inhibitor concentration by using the table shown in FIG. 6.

The control unit 100 replaces a part of the second etching liquid (S30). To elaborate, the control unit 100 drains the part of the second etching liquid by the phosphoric acid aqueous solution drain unit 41. Then, after draining the part of the second etching liquid, the control unit 100 supplies the reserve liquid from the temperature control tank 47 into the outer tub 46, and controls the SiO₂ precipitation inhibitor supply unit 43 to supply the SiO₂ precipitation inhibitor into the outer tub 46.

At this time, the control unit 100 controls the supply amounts of the reserve liquid and the SiO₂ precipitation inhibitor such that the SiO₂ precipitation inhibitor concentration of the second etching liquid reaches the set SiO₂ precipitation inhibitor concentration. That is, the control unit 100 controls the supply amounts of the reserve liquid and the SiO₂ precipitation inhibitor such that the SiO₂ precipitation inhibitor concentration of the second etching liquid is not changed before and after replacing the second etching liquid.

The control unit 100 determines whether the second etching processing is finished (S31). By way of example, if it is not the second timing (S27: No), the control unit 100 determines whether the second etching processing is finished.

To elaborate, the control unit 100 determines whether the elapsed time after the beginning of the second etching processing has reached a processing termination time. If the second etching processing is finished (S31: Yes), the control unit 100 ends the current processing. If the second etching processing is not finished (S31: No), the control unit 100 returns back to the aforementioned process and determines whether it is the first timing (S23).

As stated above, the control unit 100 controls the supply amount of the SiO₂ precipitation inhibitor such that the SiO₂ precipitation inhibitor concentration in the second etching processing is regulated to the set SiO₂ precipitation inhibitor concentration which is set based on the temperature of the etching liquid.

Now, an exhaust control over the processing tub 27 for etching will be explained with reference to FIG. 7. FIG. 7 is a flowchart for describing an exhausting processing of the processing tub 27 for etching.

The control unit 100 determine whether a total supply amount of the SiO₂ precipitation inhibitor in the second etching processing is equal to or larger than a predetermined amount (S40).

If the total supply amount is less than the predetermined amount (S40: Yes), the control unit 100 controls the switching valve 93 such that an exhaust gas from the processing chamber 80 is discharged to the acid-based processing unit 94 (S41).

If the total supply amount is equal or larger than the predetermined amount (S40: No), the control unit 100 controls the switching vale 93 such that the exhaust gas is discharged to the organic-based processing unit 95 (S42).

Further, the control unit 100 may control the switching valve 93 based on a ratio of the SiO₂ precipitation inhibitor contained in the exhaust gas. By way of example, the control unit 100 may control the switching valve 93 such that the exhaust gas is discharged to the organic-based processing unit 95 when the SiO₂ precipitation inhibitor concentration in the exhaust gas is equal to or higher than a preset concentration whereas the exhaust gas is discharged to the acid-based processing unit 94 when the SiO₂ precipitation inhibitor concentration in the exhaust gas is less than the preset concentration.

Furthermore, the control unit 100 may control the switching valve 93 depending on whether or not the etching processing is being performed. By way of example, the control unit 100 may control the switching valve 93 such that the exhaust gas is discharged to the acid-based processing unit 94 when the etching processing is being performed whereas the exhaust gas is discharged to the organic-based processing unit 95 when the etching processing is not being performed.

Further, the acid-based processing unit 94 and the organic-based processing unit 95 may be arranged in series, and the exhaust gas may be purified by discharging the exhaust gas to the two processing units consecutively.

In the substrate processing apparatus 1, the supply amount of the SiO₂ precipitation inhibitor is controlled to achieve the set SiO₂ precipitation inhibitor concentration which is set based on the temperature of the second etching liquid. Accordingly, the SiO₂ precipitation inhibitor concentration of the second etching liquid is regulated to a value suitable for the temperature of the second etching liquid. Therefore, in the second etching processing, the selectivity for etching only the nitride film can be improved, and the precipitation of the silicon oxide can be suppressed.

In the substrate processing apparatus 1, the etching processing is begun by using the first etching liquid in which the SiO₂ precipitation inhibitor is not mixed. Then, after the silicon concentration of the first etching liquid reaches the predetermined silicon concentration, the etching processing is performed with the second etching liquid in which the SiO₂ precipitation inhibitor is mixed. Accordingly, the consumption amount of the SiO₂ precipitation inhibitor can be reduced, so that cost can be cut.

In the substrate processing apparatus 1, the supply amount of the SiO₂ precipitation inhibitor is controlled based on the elapsed time of the etching processing. Accordingly, even when the silicon concentration cannot be accurately detected in the substrate processing apparatus 1, the supply amount of the SiO₂ precipitation inhibitor can be controlled, so that the precipitation of the silicon oxide can be suppressed.

In the substrate processing apparatus 1, the exhaust gas discharged from the processing tub 27 for etching is purified by using the acid-based processing unit 94 configured to remove the acidic material from the exhaust gas and the organic-based processing unit 95 configured to remove the organic material from the exhaust gas. Accordingly, the exhaust gas discharged to the outside can be suppressed from containing the acidic material and the organic material therein.

The substrate processing apparatus 1 is equipped with the switching valve 93 configured to introduce the exhaust gas selectively into either the acid-based processing unit 94 or the organic-based processing unit 95 which are arranged in parallel. Accordingly, the exhaust gas can be introduced into either the acid-based processing unit 94 or the organic-based processing unit 95 depending on the material contained therein. Therefore, it is possible to discharge the exhaust gas in which the material contained therein is appropriately removed to the outside.

Furthermore, in the above-described exemplary embodiment, though the determination upon the concentration of the material contained in the etching liquid, for example, the silicon concentration and the SiO₂ precipitation inhibitor concentration is made based on the elapsed time, it may be possible to measure each concentration by using a concentration meter. By way of example, a silicon concentration meter configured to detect the silicon concentration and a SiO₂ precipitation inhibitor concentration meter configured to detect the SiO₂ precipitation inhibitor concentration may be provided at the outer tub 46. The control unit 100 may made the aforementioned determinations based on the detected concentrations.

Moreover, in case of detecting the SiO₂ precipitation inhibitor concentration, a concentration of a material generated by adding the SiO₂ precipitation inhibitor may be detected.

Accordingly, the concentration of each material contained in the etching liquid can be accurately detected, so that the SiO₂ precipitation inhibitor concentration, for example, can be adjusted accurately. Therefore, in the etching processing, the selectivity for etching only the nitride film can be improved, and the precipitation of the silicon oxide can be further suppressed.

In addition, though the SiO₂ precipitation inhibitor is supplied into the outer tub 46 in the above-described exemplary embodiment, the exemplary embodiment is not limited thereto. By way of example, the SiO₂ precipitation inhibitor may be supplied into the temperature control tank 47 or into the supply line 70 or the phosphoric acid aqueous solution supply line 40B. In such a case as well, the control unit 100 controls the supply amount of the SiO₂ precipitation inhibitor such that the SiO₂ precipitation inhibitor concentration in the second etching processing is regulated to the set SiO₂ precipitation inhibitor concentration which is set based on the temperature of the etching liquid.

Furthermore, depending on a process of the etching processing, the phosphoric acid concentration may be increased during the etching processing. In this case, since the nitride film is difficult to etch, the SiO₂ precipitation inhibitor concentration may be set to be low. Further, since a concentration of silicon (Si) ions is increased as the process of the etching processing proceeds, it may be possible to increase the concentration of the silicon precipitation inhibitor based on the concentration of the silicon ions.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus, comprising:
a SiO₂ precipitation inhibitor supply unit configured to supply a SiO₂ precipitation inhibitor to be mixed into a phosphoric acid processing liquid used in performing an etching processing in a substrate processing tub; and
a control unit configured to set a SiO₂ precipitation inhibitor concentration contained in the phosphoric acid processing liquid based on a temperature of the phosphoric acid processing liquid, and control a supply amount of the SiO₂ precipitation inhibitor to achieve the set SiO₂ precipitation inhibitor concentration.

2. The substrate processing apparatus of claim 1,
wherein the control unit supplies the SiO₂ precipitation inhibitor when a silicon concentration of the phosphoric acid processing liquid becomes equal to or higher than a preset silicon concentration in a state that the SiO₂ precipitation inhibitor is not mixed in the phosphoric acid processing liquid.

3. The substrate processing apparatus of claim 1,
wherein the control unit controls the supply amount of the SiO₂ precipitation inhibitor based on a processing time of the etching processing.

4. The substrate processing apparatus of claim 1,
wherein the control unit detects the SiO₂ precipitation inhibitor concentration contained in the phosphoric acid processing liquid, and
the control unit controls the supply amount of the SiO₂ precipitation inhibitor based on the detected SiO₂ precipitation inhibitor concentration.

5. The substrate processing apparatus of claim 1, further comprising:
an acid-based processing unit configured to remove an acidic material from an exhaust gas discharged from the substrate processing tub; and
an organic-based processing unit configured to remove an organic material from the exhaust gas discharged from the substrate processing tub.

6. The substrate processing apparatus of claim 5, further comprising:
a switching unit configured to introduce the exhaust gas selectively into either the acid-based processing unit or the organic-based processing unit which are arranged in parallel.

7. A substrate processing method, comprising:
supplying a SiO₂ precipitation inhibitor to be mixed into a phosphoric acid processing liquid used in performing an etching processing in a substrate processing tub; and
setting a SiO₂ precipitation inhibitor concentration contained in the phosphoric acid processing liquid based on a temperature of the phosphoric acid processing liquid, and controlling a supply amount of the SiO₂ precipitation inhibitor to achieve the set SiO₂ precipitation inhibitor concentration.

8. A computer-readable recording medium having thereon computer-executable instructions that, in response to execution, cause a substrate processing apparatus to perform a substrate processing method as claimed in claim 7.
